(19) United States
(12) Patent Application Publication
(10) Pub. No.: US 2025/0030422 A1
(43) Pub. Date: Jan. 23, 2025

(54) COMPACT INTEGRATED CIRCUIT INPUT WITH LEVEL-SHIFTING TO SUPPORT RANGE OF I/O VOLTAGES

(71) Applicant: Raytheon Company, Waltham, MA (US)

(72) Inventors: Micky R. Harris, Lompoc, CA (US); Magathi J. Willis, Broomfield, CO (US)

(21) Appl. No.: 18/353,996

(22) Filed: Jul. 18, 2023

(51) Int. Cl. H03K 19/0185

(52) U.S. Cl. CPC H03K 19/018507

(57) ABSTRACT

An apparatus includes an input circuit configured to level-shift an input signal and generate an output signal having a voltage range different than a voltage range of the input signal. The input circuit includes (i) a blocking gate configured to level shift the input signal and (ii) an inverter or buffer configured to generate the output signal based on an output of the blocking gate. The input circuit is configured to generate the output signal such that the voltage range of the output signal spans between a first voltage provided to the inverter or buffer and a second voltage provided to the inverter or buffer. The blocking gate may include a transistor, a source or drain of the transistor may be configured to receive the input signal, and a gate of the transistor may be configured to receive the first voltage. The first voltage may include a core voltage of an integrated circuit device.

### TECHNICAL FIELD

This disclosure relates generally to integrated circuits. More specifically, this disclosure relates to a compact integrated circuit input with level-shifting to support a range of input/output (I/O) voltages.

### BACKGROUND

Semiconductor chips and other integrated circuit devices are typically designed to receive input signals from and provide output signals to external circuits or other external components. For example, integrated circuit devices often include input/output (I/O) pads, which represent conductive pads that are electrically coupled to circuit components within the integrated circuit devices. The I/O pads can be bonded or otherwise electrically connected to wires, solder bumps, printed circuit board (PCB) traces, or other conductive pathways in order to electrically couple the integrated circuit devices to external components.

### SUMMARY

This disclosure relates to a compact integrated circuit input with level-shifting to support a range of input/output (I/O) voltages.

In a first embodiment, an apparatus includes an input circuit configured to level-shift an input signal and generate an output signal having a voltage range different than a voltage range of the input signal. The input circuit includes (i) a blocking gate configured to level shift the input signal and (ii) an inverter or buffer configured to generate the output signal based on an output of the blocking gate. The input circuit is configured to generate the output signal such that the voltage range of the output signal spans between a first voltage provided to the inverter or buffer and a second voltage provided to the inverter or buffer.

In a second embodiment, a system includes an integrated circuit device having one or more I/O pads. The system also includes at least one input circuit associated with at least one of the one or more I/O pads. Each input circuit is configured to level-shift an input signal received at the associated I/O pad and generate an output signal having a voltage range different than a voltage range of the input signal. Each input circuit includes (i) a blocking gate configured to level shift the input signal received at the associated I/O pad and (ii) an inverter or buffer configured to generate the output signal based on an output of the blocking gate. The input circuit is configured to generate the output signal such that the voltage range of the output signal spans between a first voltage provided to the inverter or buffer and a second voltage provided to the inverter or buffer.

In a third embodiment, a method includes receiving an input signal. The method also includes level-shifting the input signal to generate an output signal having a voltage range different than a voltage range of the input signal using an input circuit. The input circuit includes (i) a blocking gate that level shifts the input signal and (ii) an inverter or buffer that generates the output signal based on an output of the blocking gate. The input circuit generates the output signal such that the voltage range of the output signal spans between a first voltage provided to the inverter or buffer and a second voltage provided to the inverter or buffer.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1 illustrates an example integrated circuit device having one or more inputs with level-shifting to support a range of input/output (I/O) voltages according to this disclosure;

FIG. 2 illustrates an example compact integrated circuit input with level-shifting to support a range of I/O voltages according to this disclosure:

FIG. 3 illustrates an example timing diagram associated with a compact integrated circuit input with level-shifting to support a range of I/O voltages according to this disclosure; and

FIG. 4 illustrates an example method for providing level-shifting in a compact integrated circuit input to support a range of I/O voltages according to this disclosure.

### DETAILED DESCRIPTION

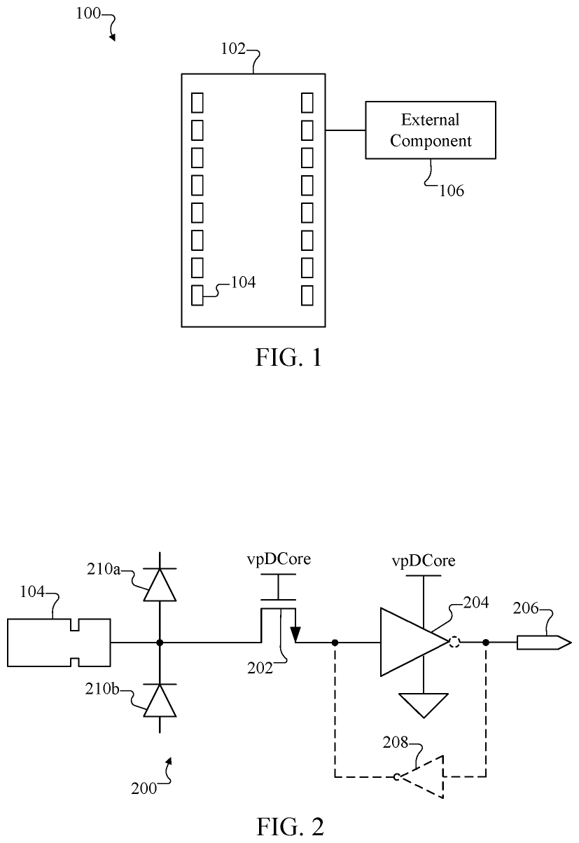

FIGS. 1 through 4, described below, and the various embodiments used to describe the principles of the present disclosure are by way of illustration only and should not be construed in any way to limit the scope of this disclosure, Those skilled in the art will understand that the principles of the present disclosure may be implemented in any type of suitably arranged device or system.

As noted above, semiconductor chips and other integrated circuit devices are typically designed to receive input signals from and provide output signals to external circuits or other external components. For example, integrated circuit devices often include input/output (I/O) pads, which represent conductive pads that are electrically coupled to circuit components within the integrated circuit devices. The I/O pads can be bonded or otherwise electrically connected to wires, solder bumps, printed circuit board (PCB) traces, or other conductive pathways in order to electrically couple the integrated circuit devices to external components.

It is common for semiconductor chips and other integrated circuit devices to operate using core voltages that are different from voltages used by external circuits or other external components interacting with the integrated circuit devices. For example, an integrated circuit device may operate using a core voltage of 1.2 volts, while an external component may operate using a voltage of 1.8 volts to 3.3 volts or more. Because of this, input circuits used in integrated circuit devices often need to function across various I/O voltage levels. Some approaches provide input circuits having single input stages to handle these different voltages, but these approaches typically have limited operating ranges. Other approaches provide input circuits having rail-to-rail comparators with self-generated reference levels to handle these different voltages, but these approaches typically involve complex circuitry that can increase the size, weight, power, and cost of the integrated circuit devices. In addition, these approaches often use multiple voltage supplies to accommodate different supply voltages or use complex circuitry to compare different voltage thresholds to incoming voltage levels.

This disclosure provides a compact integrated circuit input with level-shifting to support a range of I/O voltages. As described in more detail below, an input circuit for a semiconductor device or other integrated circuit device includes a blocking gate and a first inverter or buffer coupled in series. The blocking gate can be coupled to an I/O pad or otherwise configured to receive and level shift an input signal. In some cases, the blocking gate may be formed using a transistor. Also, the input signal may be received at a source or drain of the transistor, rather than at a gate of the transistor. The gate of the transistor can be coupled to receive a core voltage or other voltage of the integrated circuit device, and the transistor can have a low threshold voltage or represent a native device with a near-zero threshold drop. The first inverter or buffer generates an output signal based on the output of the blocking gate, and the first inverter or buffer can be coupled to receive the core or other voltage of the integrated circuit device as a supply voltage and to receive a lower voltage (such as a ground voltage). Collectively, the blocking gate and the first inverter or buffer can be used to generate the output signal, which represents a level-shifted version of the input signal. For instance, the output signal generated using the blocking gate and the first inverter or buffer can have a maximum voltage level matching the core or other voltage of the integrated circuit device. A second inverter or buffer may optionally be coupled as a feedback inverter or buffer across the first inverter or buffer.

The input circuit here therefore operates to convert an input signal (which can have voltages spanning a first voltage range) into an output signal (which can have voltages spanning a second voltage range different from the first voltage range), thereby providing level-shifting of the input signal. The first voltage range can be variable or unknown ahead of time and may be based on the external component(s) to be coupled to the input circuit, and the second voltage range can be fixed based on the core or other voltage of the integrated circuit device. As a particular example, the input circuit may be used to level-shift an input signal having a voltage up to 1.8-3.3 volts to an output signal having a voltage up to 1.2 volts (although these values are for illustration only). Note that the term “span” here can encompass a range between two voltages inclusive or exclusive of those two voltages.

In this way, the input circuit is able to perform level-shifting between an input voltage level and a core or other voltage level. This allows the associated integrated circuit device to be used with various external components that provide a wide range of input voltage levels. Also, this level-shifting can be achieved using an input circuit that is smaller and less complex than conventional circuits, which can help to reduce the size, weight, power, and cost of the integrated circuit device. This can be particularly beneficial when an integrated circuit device includes numerous input circuits. Moreover, since the input signal is not connected directly to the gate of the transistor forming the blocking gate, this can provide improved electrostatic discharge (ESD) protection or other protection for the blocking gate. This can be because no conductive pad is needed for the gate of the transistor forming the blocking gate, so there is no ESD protection needed for the gate of the transistor. Further, in some cases, one or more thin-oxide devices may be used in the input circuit, which can provide higher switching speeds for the input circuit. In addition, in some cases, the second inverter or buffer can optionally be used to improve the rail-to-rail switching of the input circuit.

FIG. 1 illustrates an example integrated circuit device 100 having one or more inputs with level-shifting to support a range of I/O voltages according to this disclosure. As shown in FIG. 1, the integrated circuit device 100 is formed using a semiconductor chip 102 having one or more I/O pads 104. The semiconductor chip 102 represents an integrated circuit device that can receive at least one input signal, where the at least one input signal may need to undergo level-shifting from voltage levels within a wide range of voltages to a voltage level associated with a core or other voltage of the integrated circuit device. In this example, the integrated circuit device 100 takes the form of a rectangular semiconductor chip 102, although the integrated circuit device 100 may have any other suitable form. The semiconductor chip 102 includes any suitable integrated circuit device having one or more inputs. As particular (non-limiting) examples, the semiconductor chip 102 may represent a microprocessor, microcontroller, digital signal processor (DSP), application-specific integrated circuit (ASIC), field programmable gate array (ASIC), memory chip, or specialty semiconductor chip.

Each I/O pad 104 represents a conductive structure on or in the semiconductor chip 102. Each I/O pad 104 is electrically coupled to one or more circuit components within the semiconductor chip 102. Each I/O pad 104 can also be bonded or otherwise electrically connected to a wire, solder bump, PCB trace, or other conductive pathway. This allows each I/O pad 104 to receive an input signal (such as a data or power signal) for or provide an output signal from one or more circuit components within the semiconductor chip 102. Among other things, this enables the semiconductor chip 102 to interact with one or more external components 106. While a single external component 106 is shown here, the semiconductor chip 102 may be coupled to any suitable number of external components 106. Each external component 106 may represent another circuit component or other electrical device or system that can interact with the integrated circuit device 100. Note that the number and arrangement of the I/O pads 104 shown here are for illustration only. The semiconductor chip 102 may include any suitable number of I/O pads 104 in any suitable arrangement. The I/O pads 104 may also be positioned on any suitable surface(s) of the semiconductor chip 102.

As described in more detail below, each I/O pad 104 used for input may be coupled to an input circuit that supports level-shifting across a range of voltage levels. For example, each input circuit may be configured to level-shift an input signal from a voltage level used by an external component 106 to a core voltage level or other voltage level used by the semiconductor chip 102. As a particular example, the semiconductor chip 102 may operate using a core voltage of 1.2 volts, while an external component may provide an input signal having a voltage up to 1.8 volts to 3.3 volts. Each input circuit can be used to support level-shifting while obtaining various advantages, such as a simplified design, improved ESD protection, improved switching speed, improved rail-to-rail switching, or any combination thereof.

Although FIG. 1 illustrates one example of an integrated circuit device 100 having one or more inputs with level-shifting to support a range of I/O voltages, various changes may be made to FIG. 1. For example, the integrated circuit device 100 may have any other suitable form or design. In general, a compact integrated circuit input with level-shifting to support a range of I/O voltages may be used with any suitable integrated circuit devices,

FIG. 2 illustrates an example compact integrated circuit input 200 with level-shifting to support a range of I/O voltages according to this disclosure. For ease of explanation, the integrated circuit input 200 shown in FIG. 2 is described as being used in the integrated circuit device 100 shown in FIG. 1. However, the integrated circuit input 200 may be used with any other suitable device or system.

As shown in FIG. 2, the integrated circuit input 200 represents an input circuit that includes or is used in conjunction with an I/O pad 104 that receives an incoming input signal. The incoming input signal is provided to a blocking gate 202, which is coupled to a first inverter or buffer 204. The blocking gate 202 can be used to level shift the input signal from the I/O pad 104 and provide the level-shifted input signal to the first inverter or buffer 204. As a result, the blocking gate 202 can block the high voltage of the incoming input signal from reaching the first inverter or buffer 204. The blocking gate 202 includes any suitable structure configured to level shift an electrical signal, such as a transistor. As a particular example, the blocking gate 202 may represent a complementary metal oxide semiconductor (CMOS) transistor, such as an n-type metal oxide semiconductor (NMOS) transistor. The first inverter or buffer 204 is configured to receive (and possibly invert) an electrical signal from the blocking gate 202 and generate an output signal 206. For example, when the blocking gate 202 outputs a low voltage, the first inverter or buffer 204 may (when implemented as an inverter) invert the low voltage to a high voltage in the output signal 206, or the first inverter or buffer 204 may (when implemented as a buffer) output the low voltage in the output signal 206. The transistor used to form the blocking gate 202 may take any suitable form, such as a device with a low threshold voltage or a native thick-gate device.

As can be seen in FIG. 2, the I/O pad 104 is coupled to a source or a drain (not a gate) of the transistor forming the blocking gate 202. As a result, the incoming input signal from the I/O pad 104 is provided to the source or drain and not the gate of the transistor. The gate of the transistor is coupled to receive a core voltage (denoted vpDCore) of the integrated circuit device 100. Typically, the core voltage vpDCore represents a fixed voltage generated by or provided to the integrated circuit device 100 (although inherent ripples or other minor variations may be present simply due to the nature of electrical components). The core voltage vpDCore may represent the power supply voltage used by the integrated circuit device 100.

In some embodiments, the core voltage vpDCore may represent a voltage of 1.2 volts, although any other suitable voltage generated or used by the integrated circuit device 100 may be provided to the gate of the transistor forming the blocking gate 202. Also, in some embodiments, the transistor forming the blocking gate 202 can have a low threshold voltage, which means that the transistor may need a relatively small difference between its gate and source voltages to become conductive. In addition, in some embodiments, the first inverter or buffer 204 may be coupled to receive the core voltage vpDCore of the integrated circuit device 100 as a supply voltage and to receive a lower voltage (such as a ground voltage). As a result, the output of the first inverter or buffer 204 typically varies between the ground or other lower voltage and the core voltage vpDCore. The electrical pathways that provide the core voltage vpDCore and the ground or other lower voltage are often referred to as voltage “rails,” where one rail provides a larger supply voltage and another rail provides the ground or other lower voltage.

In this configuration, the integrated circuit input 200 can level-shift the input signal received from the I/O pad 104 in order to generate the output signal 206. For example, the output signal 206 can include voltages spanning a range from 0 volts (ground) to the core voltage vpDCore since those are the voltages used by the first inverter or buffer 204. This result can be achieved regardless of how much the input signal received from the I/O pad 104 exceeds the core voltage vpDCore. Thus, for instance, the core voltage vpDCore may represent a voltage of 1.2 volts, while the input signal from the I/O pad 104 may span a range of voltages tip to 1.8 volts, up to 3.3 volts, or even higher. Since the input signal from the I/O pad 104 is not coupled to the gate of the transistor forming the blocking gate 202, this can provide improved ESD protection for the blocking gate 202 because there is no need for a conductive pad to be used with the gate of the transistor forming the blocking gate 202. Rather, the gate of the transistor can be configured to receive the core voltage vpDCore without using any conductive pads. If the first inverter or buffer 204 is implemented using a thin-oxide device, this can also provide improved switching speed for the integrated circuit input 200.

A second inverter or buffer 208 may optionally be coupled across the first inverter or buffer 204. The second inverter or buffer 208 can have its input coupled to the output of the first inverter or buffer 204 and its output coupled to the input of the first inverter or buffer 204. The second inverter or buffer 208 therefore operates to invert or buffer the output of the first inverter 204 and feed back the inverted or buffered output as input to the first inverter or buffer 204. The second inverter or buffer 208 can represent a “weaker” inverter or buffer, and the first inverter or buffer 204 can represent a “stronger” inverter or buffer. This indicates that the first inverter or buffer 204 can generally operate by inverting or buffering the output of the blocking gate 202. The second inverter or buffer 208 can help to increase the speed at which the first inverter or buffer 204 transitions its output from rail-to-rail (meaning from 0 volts to vpDCore or vice versa in this example) but generally cannot override the input signal received from the I/O pad 104. This can provide improved rail-to-rail switching for the integrated circuit input 200.

Two diodes 210a-210b may be coupled to the I/O pad 104 between the I/O pad 104 and the blocking gate 202. The diodes 210a-210b represent clamping diodes that can be used to provide additional protection to the integrated circuit input 200, such as by supporting ESD protection for the blocking gate 202. As a particular example, the diode 210a can have its cathode coupled to the I/O pad 104, and the diode 210b can have its anode coupled to the I/O pad 104. This effectively clamps the voltage present on the I/O pad 104 so that the voltage is not too high or too low.

Although FIG. 2 illustrates one example of a compact integrated circuit input 200 with level-shifting to support a range of IO voltages, various changes may be made to FIG. 2. For example, while specific components in the integrated circuit input 200 are shown in FIG. 2, other circuit components configured to perform the same or similar functions may be used here.

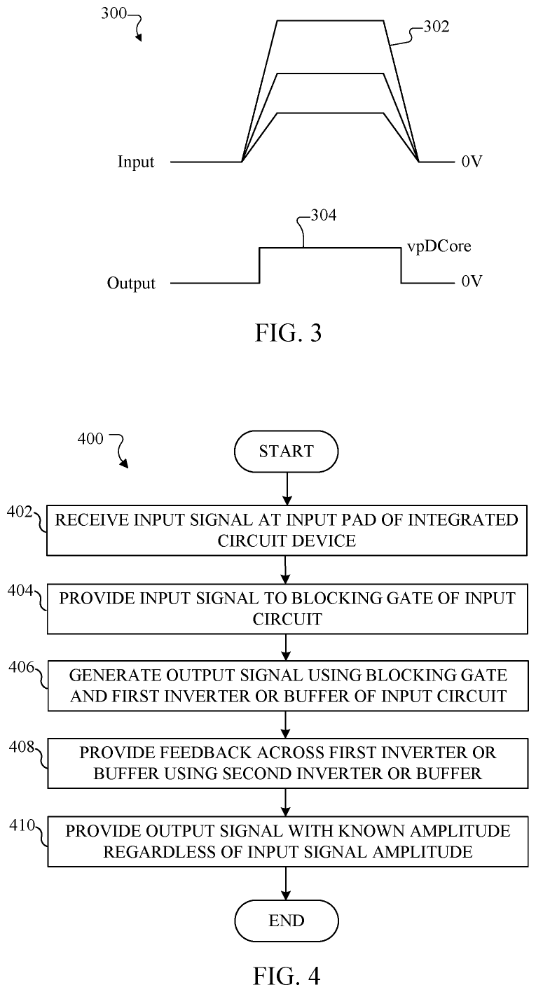

FIG. 3 illustrates an example timing diagram 300 associated with a compact integrated circuit input with level-shifting to support a range of I/O voltages according to this disclosure. For ease of explanation, the timing diagram 300 shown in FIG. 3 is described as being associated with the integrated circuit input 200 shown in FIG. 2, which can be used in the integrated circuit device 100 shown in FIG. 1. However, the timing diagram 300 may represent the operation of any other suitable input circuit, and the input circuit may be used with any other suitable device or system.

As shown in FIG. 3, the timing diagram 300 includes an input signal 302 and a corresponding output signal 304. The input signal 302 represents a signal provided to the integrated circuit device 100, such as an input signal provided to an I/O pad 104 of the integrated circuit device 100 by an external component 106. The output signal 304 represents a signal generated by the integrated circuit input 200 in the integrated circuit device 100 that is coupled to the I/O pad 104, such as the output signal 206. The output signal 304 can be provided from the integrated circuit input 200 to one or more other components of the integrated circuit device 100 for use. The actual usage of the output signal 304 by the one or more other components of the integrated circuit device 100 can vary widely based on the specific design and function(s) of the integrated circuit device 100.

As can be seen in FIG. 3, the input signal 302 may span a range of voltages, such as from 0 volts to a higher voltage. In this example, three higher voltage levels are illustrated, indicating that the input signal 302 being received might achieve one of multiple distinct voltage levels. As particular examples, the input signal 302 received at the I/O pad 104 of the integrated circuit device 100 may have a maximum voltage of 1.8 volts, 2.5 volts, or 3.3 volts. Note that these values are examples only and can vary depending on the implementation. Also, in some cases, these different maximum voltages may be defined according to different I/O voltage standards, such as different standards associated with different external components 106 or different types of external components 106.

Regardless of the voltage range of the input signal 302, the resulting output signal 304 may span a fixed range of voltages, such as from 0 volts to the core voltage vpDCore. This can be achieved regardless of the voltage level contained in the input signal 302 due to the operation of the blocking gate 202 and the first inverter or buffer 204, which convert the input signal 302 (regardless of its amplitude) into the output signal 304 (which has a known fixed amplitude). Because the transistor forming the blocking gate 202 can have a low threshold voltage, the integrated circuit input 200 can be used to receive signals having different (and possibly significantly different) input voltage ranges, such as when the integrated circuit input 200 can interface with devices supporting different I/O voltage standards. The level-shifting can be achieved while obtaining the various benefits described above, such as use of a simplified design, improved ESD protection, improved switching speed, improved rail-to-rail switching, or a combination of these benefits. In some embodiments, the integrated circuit input 200 can operate successfully to perform level-shifting of any voltage input level greater than or equal to the core voltage vpDCore without using any additional reference voltage or power supply voltage that is higher than the core voltage vpDCore.

Although FIG. 3 illustrates one example of a timing diagram 300 associated with a compact integrated circuit input 200 with level-shifting to support a range of I/O voltages, various changes may be made to FIG. 3. For example, the specific signals shown in FIG. 3 are examples only, and the input signals provided to and the output signals generated by integrated circuit inputs 200 can vary widely depending on the circumstances. FIG. 3 is merely meant to illustrate one example of the type of level-shifting that can be achieved using the integrated circuit input 200. Also, the contents of the timing diagram 300 represent ideal operation of the integrated circuit input 200 since some variations are usually present in any given electrical signals.

FIG. 4 illustrates an example method 400 for providing level-shifting in a compact integrated circuit input to support a range of I/O voltages according to this disclosure. For ease of explanation, the method 400 shown in FIG. 4 is described as being performed using the integrated circuit input 200 shown in FIG. 2 within the integrated circuit device 100 shown in FIG. 1. However, the method 400 may be used with any other suitable input circuit, device, or system.

As shown in FIG. 4, an input signal is received at an I/O pad of an integrated circuit device at step 402. This may include, for example, the integrated circuit device 100 receiving an input signal at an I/O pad 104 from an external component 106. Note, however, that the input signal may be obtained in any other suitable manner. The input signal is provided to a blocking gate of an input circuit in the integrated circuit device at step 404. This may include, for example, the source or drain of a transistor forming the blocking gate 202 receiving the input signal from the I/O pad 104. The input signal can optionally be clamped using the diodes 210a-210b prior to reaching the source or drain of the transistor forming the blocking gate 202. A gate of the transistor forming the blocking gate 202 can be coupled to receive the core voltage vpDCore or other voltage of the integrated circuit device 100.

An output signal is generated using the blocking gate and a first inverter or buffer of the input circuit at step 406. This may include, for example, the transistor forming the blocking gate 202 level-shifting the input signal from the I/O pad 104. Since the gate of the transistor forming the blocking gate 202 can be connected to receive the core voltage vpDCore, the transistor forming the blocking gate 202 may remain on, but the output of the transistor forming the blocking gate 202 may only be able to swing between the core voltage vpDCore and the threshold voltage. This may also include the first inverter or buffer 204 inverting or buffering the output of the blocking gate 202 to generate an output signal 206. Feedback may optionally be provided across the first inverter or buffer using a second inverter or buffer at step 408. This may include, for example, the second inverter or buffer 208 inverting or buffering the output of the first inverter or buffer 204 and providing the inverted or buffered output back to the input of the first inverter or buffer 204.

An output signal having a known amplitude (regardless of the input signal's amplitude) is provided at step 410. This may include, for example, the output signal 206 being provided from the integrated circuit input 200 to one or more other components of the integrated circuit device 100 for use. As described above, the integrated circuit input 200 can level-shift the input signal from the I/O pad 104 so that the output signal 206 has a known amplitude, such as a voltage range from 0 volts to the core voltage vpDCore. This can be achieved because the blocking gate 202 and the first inverter or buffer 204 operate to generate the output signal 206 having a voltage span defined by the voltage rails of the integrated circuit input 200. The integrated circuit input 200 here is able to process the input signal from the I/O pad 104 even if the input signal from the I/O pad 104 is 1.5 times, double, triple, or even higher than the core voltage vpDCore of the integrated circuit device 100. In general, this disclosure is not limited to any specific voltage range for the input signal or the output signal.

Although FIG. 4 illustrates one example of a method 400 for providing level-shifting in a compact integrated circuit input to support a range of I/O voltages, various changes may be made to FIG. 4. For example, while shown as a series of steps, various steps in FIG. 4 may overlap, occur in parallel, occur in a different order, or occur any number of times (including zero times).

Note that while the description above has provided specific numerical values for different features, these numerical values are examples only. For instance, the description above has provided specific numerical values for various core or other voltages. However, these numerical values are for illustration and explanation only and do not limit the scope of this disclosure to those specific voltages. Moreover, the specific numerical values given above are approximate values only and can vary based on various factors, such as manufacturing tolerances and environmental conditions.

The following describes example embodiments of this disclosure that implement or relate to a compact integrated circuit input with level-shifting to support a range of I/O voltages. However, other embodiments may be used in accordance with the teachings of this disclosure.

In a first embodiment, an apparatus includes an input circuit configured to level-shift an input signal and generate an output signal having a voltage range different than a voltage range of the input signal. The input circuit includes (i) a blocking gate configured to level shift the input signal and (ii) an inverter or buffer configured to generate the output signal based on an output of the blocking gate. The input circuit is configured to generate the output signal such that the voltage range of the output signal spans between a first voltage provided to the inverter or buffer and a second voltage provided to the inverter or buffer.

Any single one or any suitable combination of the following features may be used with the first embodiment. The blocking gate may include a transistor. A source or a drain of the transistor may be configured to receive the input signal A gate of the transistor may be configured to receive the first voltage. The first voltage may include a core voltage of an integrated circuit device. The gate of the transistor may not be configured to receive the input signal and may lack a conductive pad used to provide the first voltage to the gate of the transistor. The transistor may include a native thick-gate or low threshold voltage thick-gate device and may support receipt of different input signals having different input voltage ranges. The inverter or buffer may include a thin-oxide device. The inverter or buffer may include a first inverter or buffer, and the input circuit may include a second inverter or buffer coupled across the first inverter or buffer and configured to provide feedback (where the second inverter or buffer may have an input coupled to an output of the first inverter or buffer and an output coupled to an input of the first inverter or buffer).

In a second embodiment, a system includes an integrated circuit device having one or more I/O pads. The system also includes at least one input circuit associated with at least one of the one or more I/O pads. Each input circuit is configured to level-shift an input signal received at the associated I/O pad and generate an output signal having a voltage range different than a voltage range of the input signal. Each input circuit includes (i) a blocking gate configured to level shift the input signal received at the associated I/O pad and (ii) an inverter or buffer configured to generate the output signal based on an output of the blocking gate. The input circuit is configured to generate the output signal such that the voltage range of the output signal spans between a first voltage provided to the inverter or buffer and a second voltage provided to the inverter or buffer.

Any single one or any suitable combination of the following features may be used with the second embodiment. For each input circuit, the blocking gate may include a transistor, and a source or a drain of the transistor may be configured to receive the input signal. A gate of the transistor may be configured to receive the first voltage. The first voltage may include a core voltage of the integrated circuit device. The gate of the transistor may not be configured to receive the input signal and may lack a conductive pad used to provide the first voltage to the gate of the transistor. The transistor may include a native thick-gate or low threshold voltage thick-gate device and may support receipt of different input signals having different input voltage ranges. The inverter or buffer may include a thin-oxide device. For each input circuit, the inverter or buffer may include a first inverter or buffer, and the input circuit may include a second inverter or buffer coupled across the first inverter or buffer and configured to provide feedback (where the second inverter or buffer may have an input coupled to an output of the first inverter or buffer and an output coupled to an input of the first inverter or buffer). The integrated circuit device may include a semiconductor chip having multiple I/O pads.

In a third embodiment, a method includes receiving an input signal. The method also includes level-shifting the input signal to generate an output signal having a voltage range different than a voltage range of the input signal using an input circuit. The input circuit includes (i) a blocking gate that level shifts the input signal and (ii) an inverter or buffer that generates the output signal based on an output of the blocking gate. The input circuit generates the output signal such that the voltage range of the output signal spans between a first voltage provided to the inverter or buffer and a second voltage provided to the inverter or buffer.

Any single one or any suitable combination of the following features may be used with the third embodiment. The blocking gate may include a transistor. A source or a drain of the transistor may be configured to receive the input signal. A gate of the transistor may be configured to receive the first voltage. The first voltage may include a core voltage of an integrated circuit device.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C. and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus comprising:
an input circuit configured to level-shift an input signal and generate an output signal having a voltage range different than a voltage range of the input signal, the input circuit comprising:
a blocking gate configured to level shift the input signal; and
an inverter or buffer configured to generate the output signal based on an output of the blocking gate;
wherein the input circuit is configured to generate the output signal such that the voltage range of the output signal spans between a first voltage provided to the inverter or buffer and a second voltage provided to the inverter or buffer.

2. The apparatus of claim 1, wherein:
the blocking gate comprises a transistor; and
a source or a drain of the transistor is configured to receive the input signal.

3. The apparatus of claim 2, wherein a gate of the transistor is configured to receive the first voltage.

4. The apparatus of claim 3, wherein the first voltage comprises a core voltage of an integrated circuit device.

5. The apparatus of claim 3, wherein the gate of the transistor is not configured to receive the input signal and lacks a conductive pad, the gate of the transistor configured to receive the first voltage without using any conductive pads.

6. The apparatus of claim 2, wherein the transistor comprises a native thick-gate or low threshold voltage thick-gate device and supports receipt of different input signals having different input voltage ranges.

7. The apparatus of claim 1, wherein the inverter or buffer comprises a thin-oxide device.

8. The apparatus of claim 1, wherein:
the inverter or buffer comprises a first inverter or buffer; and
the input circuit further comprises a second inverter or buffer coupled across the first inverter or buffer and configured to provide feedback, the second inverter or buffer having an input coupled to an output of the first inverter or buffer and an output coupled to an input of the first inverter or buffer.

9. A system comprising:
an integrated circuit device comprising one or more input/output (I/O) pads; and
at least one input circuit associated with at least one of the one or more I/O pads, each input circuit configured to level-shift an input signal received at the associated I/O pad and generate an output signal having a voltage range different than a voltage range of the input signal, each input circuit comprising:
a blocking gate configured to level shift the input signal received at the associated I/O pad; and
an inverter or buffer configured to generate the output signal based on an output of the blocking gate;
wherein the input circuit is configured to generate the output signal such that the voltage range of the output signal spans between a first voltage provided to the inverter or buffer and a second voltage provided to the inverter or buffer.

10. The system of claim 9, wherein, for each input circuit:
the blocking gate comprises a transistor; and
a source or a drain of the transistor is configured to receive the input signal.

11. The system of claim 10, wherein a gate of the transistor is configured to receive the first voltage.

12. The system of claim 11, wherein the first voltage comprises a core voltage of the integrated circuit device.

13. The system of claim 11, wherein the gate of the transistor is not configured to receive the input signal and lacks a conductive pad, the gate of the transistor configured to receive the first voltage without using any conductive pads.

14. The system of claim 10, wherein the transistor comprises a native thick-gate or low threshold voltage thick-gate device and supports receipt of different input signals having different input voltage ranges.

15. The system of claim 9, wherein the inverter or buffer comprises a thin-oxide device.

16. The system of claim 9, wherein, for each input circuit:
the inverter or buffer comprises a first inverter or buffer; and
the input circuit further comprises a second inverter or buffer coupled across the first inverter or buffer and configured to provide feedback, the second inverter or buffer having an input coupled to an output of the first inverter or buffer and an output coupled to an input of the first inverter or buffer.

17. The system of claim 9, wherein the integrated circuit device comprises a semiconductor chip having multiple I/O pads.

18. A method comprising:
receiving an input signal; and
level-shifting the input signal to generate an output signal having a voltage range different than a voltage range of the input signal using an input circuit;
wherein the input circuit comprises:
a blocking gate that level shifts the input signal; and
an inverter or buffer that generates the output signal based on an output of the blocking gate; and
wherein the input circuit generates the output signal such that the voltage range of the output signal spans between a first voltage provided to the inverter or buffer and a second voltage provided to the inverter or buffer.

19. The method of claim 18, wherein:
the blocking gate comprises a transistor;
a source or a drain of the transistor is configured to receive the input signal; and
a gate of the transistor is configured to receive the first voltage.

20. The method of claim 19, wherein the first voltage comprises a core voltage of an integrated circuit device.
